(19) United States
(12) Patent Application Publication
(10) Pub. No.: US 2009/0090929 A1
(43) Pub. Date: Apr. 9, 2009

(54) LIGHT-EMITTING DIODE CHIP AND MANUFACTURING METHOD THEREOF

(75) Inventors: Sheng-Han TU, Taoyuan Hsien (TW); Gwo-Jiun SHEU, Taoyuan Hsien (TW); Chii-How CHANG, Taoyuan Hsien (TW); Kun-Yueh LIN, Taoyuan Hsien (TW)

Correspondence Address: Muncy, Geissler, Olds & Lowe, PLLC, P.O. BOX 1364, FAIRFAX, VA, 22038-1364, US

(73) Assignee: DELTA ELECTRONICS, INC.

(21) Appl. No.: 12/233,243

(22) Filed: Sep. 18, 2008

(30) Foreign Application Priority Data
Oct. 5, 2007 (TW) 096137367

(51) Int. Cl. H01L 33/00; H01L 21/00

(52) U.S. Cl. 257/102; 438/45; 257/E33.001; 257/E21.001

(57) ABSTRACT

A light-emitting diode (LED) chip includes a substrate, a first semiconductor layer, an active layer, a second semiconductor layer and a groove. The first semiconductor layer, active layer and second semiconductor layer are formed on the substrate in sequence. The groove is formed in the first semiconductor layer, the active layer and the second semiconductor layer.

### CROSS REFERENCE TO RELATED APPLICATIONS

This Non-provisional application claims priority under 35 U.S.C. §119(a) on Patent Application No(s). 096137367 filed in Taiwan, Republic of China on Oct. 5, 2007, the entire contents of which are hereby incorporated by reference.

### BACKGROUND OF THE INVENTION

1. Field of Invention

The invention relates to a light-emitting diode (LED) chip and a manufacturing method thereof.

2. Related Art

A light-emitting diode (LED) apparatus is a lighting apparatus made of semiconductor materials. The LED apparatus pertaining to a cold lighting apparatus has the advantages of low power consumption, long lifetime, high response speed and small size, and can be manufactured into an extremely small or array-type apparatus. With the continuous progress of the recent technology, the application range thereof covers an indicator of a computer or a house appliance product, a backlight source of a liquid crystal display (LCD) apparatus, a traffic sign or a vehicle indicator.

Recently, the high power LEDs are also gradually developed according to the requirement of the application. In general, the power LED is driven with the low voltage (2.5V to 6V) and the high current (about 0.35 A to 20 A) to emit light. However, the design and the control of a low-voltage high-current driving circuit are more complicated than those of a high-voltage low-current driving circuit, and the low-voltage high-current driving circuit has the higher cost. In addition, the side length of the high power LED chip is frequently longer than 1000 microns (μm). In other words, the area thereof is greater than 1 mm². Compared with the side length of the typical lower power chip, such as 610 μm or 381 μm, the high power LED has the increased rated current, watts and luminance by enlarging the area of the LED chip. However, the heat dissipating is not so easy and the light emitting efficiency is deteriorated.

FIG. 1A shows the relationships between the light emitting efficiency and the sizes of the LED chips including a sapphire substrate and a silicon carbide (SiC) substrate. As shown in FIG. 1A, it is found that the light emitting efficiency becomes lower as the size of the LED chip gets larger. In addition, as shown in FIG. 1B, it is found that the light emitting efficiency of the LED is decreased when the watts of the input power of the LED become higher.

Next, as shown in FIG. 2, a conventional LED 1 mainly has one single chip, and an N-type semiconductor layer 12, an active layer 13, a P-type semiconductor layer 14 are formed on a substrate 11 in sequence. The active layer 13 is interposed between the P-type semiconductor layer 14 and the N-type semiconductor layer 12. The LED 1 further has an N-type electrode 15 and a P-type electrode 16 respectively electrically connected to the N-type semiconductor layer 12 and the P-type semiconductor layer 14 so that the current is inputted to the LED 1 to form a loop to make the LED 1 emit the light. In addition, the active layer 13 is also referred to as a band gap layer, and the LED 1 generates different colors of light according to the variation of the band gap of the band gap layer.

In order to make the LED 1 have the uniform current density and emit the light uniformly, an electrode thereof is manufactured to have a complicated pattern 161 (sees FIGS. 3A to 3C) so that the current can flow and be distributed into the LED 1 more uniformly. However, the complicated electrode pattern increases the difficulty in designing and manufacturing the LED and increases the cost of the LED. In addition to the complicated electrode pattern, more than one gold wire has to be connected to one electrode in order to enhance the uniformity of the current so that the cost is increased and the manufacturing difficulty is increased.

Therefore, it is an important subject to provide a light-emitting diode (LED) chip and a manufacturing method thereof that can solve the above-mentioned problems.

### SUMMARY OF THE INVENTION

In view of the foregoing, an object of the invention is to provide a light-emitting diode (LED) chip, which can be driven with a high voltage and a low Current to dissipate a heat source, and a manufacturing method thereof.

To achieve the above, the invention discloses a LED chip includes a substrate, a first semiconductor layer, an active layer, a second semiconductor layer and a groove. The first semiconductor layer, active layer and second semiconductor layer are formed on the substrate in sequence. The groove is formed in the first semiconductor layer, the active layer and the second semiconductor layer.

To achieve the above, the invention also discloses a manufacturing method of a LED chip. The method includes the steps of: forming a first semiconductor layer, an active layer and a second semiconductor layer in sequence; removing a portion of the first semiconductor layer, a portion of the active layer and a portion of the second semiconductor layer to form at least one groove, wherein the first semiconductor layer is exposed from the groove; forming at least one first electrode on the exposed first semiconductor layer; forming an insulating layer in the groove; and forming at least one second electrode to cover at least a portion of the second semiconductor layer and at least a portion of the insulating layer.

In addition, the invention further discloses a manufacturing method of a LED chip. The method includes the steps of: forming a first semiconductor layer, an active layer and a second semiconductor layer in sequence; removing a portion of the first semiconductor layer, a portion of the active layer and a portion of the second semiconductor layer to form at least one groove for compartmentalizing a plurality of LED units; forming an insulating layer in the groove; removing a portion of the second semiconductor layer and a portion of the active layer of each of the LED units to expose a portion of the first semiconductor layer; forming an auxiliary insulating layer on the insulating layer to cover a portion of the second semiconductor layer and a portion of the first semiconductor layer; and forming a conductive layer electrically connected to the second semiconductor layer of each of the LED units and the first semiconductor layer of the adjacent LED unit.

As mentioned hereinabove, the LED chip manufactured according to the above-mentioned method of the invention has a plurality of LED units connected in parallel or in series. The LED units with the smaller sizes are combined to form the LED chip with the larger size so that the high light emitting efficiency of the small chip and the high power load of the large chip can be provided.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a graph showing relationships between chip sizes and light emitting efficiency in a conventional LED device;

FIG. 1B is a graph showing a relationship between input power and the light emitting efficiency in the conventional LED device;

FIG. 2 is a schematic illustration showing a structure of the conventional LED device;

FIGS. 3A to 3C are schematic illustrations showing electrode patterns of the LED device of FIG. 2;

FIG. 4 is a flow chart showing a manufacturing method of a LED chip according to a first embodiment of the invention;

FIGS. 5A to 5G are schematic illustrations showing the LED chip corresponding to the manufacturing method of FIG. 4;

FIGS. 6A to 6J are schematic top views showing various aspects of a second semiconductor layer of the LED chip according to the first embodiment of the invention;

FIG. 7 is a flow chart showing a LED chip according to a second embodiment of the invention;

FIGS. 8A to 8G are schematic illustrations showing the LED chip corresponding to the manufacturing method of FIG. 7; and

FIGS. 9A to 9C show the other three aspects of a groove C1 of FIG. 5C.

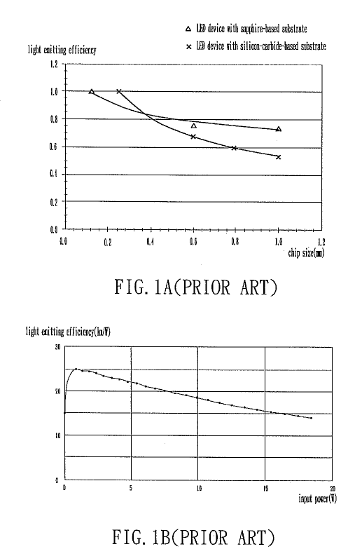

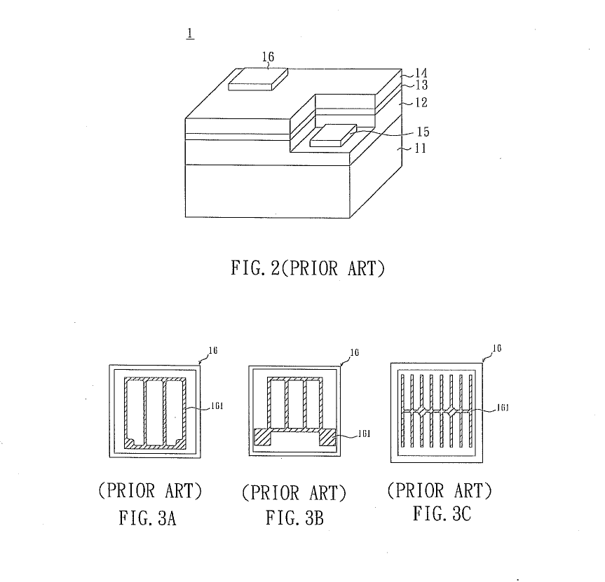

### DETAILED DESCRIPTION OF THE INVENTION

The present invention will be apparent from the following detailed description, which proceeds with reference to the accompanying drawings, wherein the same references relate to the same elements.

### First Embodiment

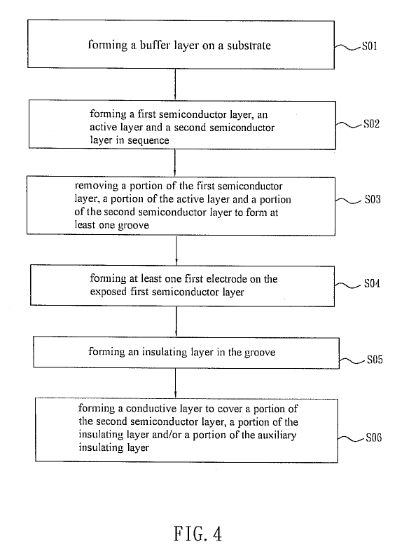

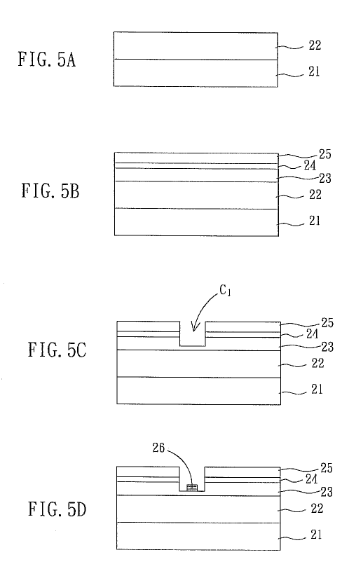

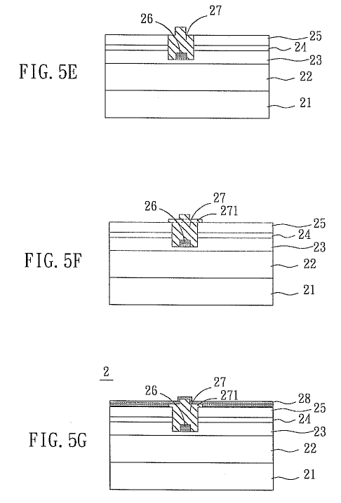

Referring to FIG. 4, a manufacturing method of a LED chip according to a first embodiment of the invention includes steps S01 to S06. Illustrations will be made in the following with reference to FIGS. 5A to 5G.

As shown in FIG. 5A, a buffer layer 22 is formed on a substrate 21 in the step S01. A material of the substrate 21 is, for example but not limited to, sapphire, silicon, silicon carbide or an alloy, and preferably has the high thermal conductivity. The buffer layer 22 is, for example but not limited to, a single layer substance or a multi-layer substance.

As shown in FIG. 5B, a first semiconductor layer 23, an active layer 24 and a second semiconductor layer 25 are formed in sequence in the step S02. The first semiconductor layer 23 can be formed on the buffer layer 22. Of course, the first semiconductor layer 23, the active layer 24 and the second semiconductor layer 25 can also be formed on an epitaxial substrate (not shown) in sequence, and then be transposed to the substrate 21 and the buffer layer 22. The semiconductor manufacturing aspect and the order are not particularly limited, and the substrate 21 and the buffer layer 22 can also be kept in a final facture or may be removed from the final facture.

In other words, the step S01 can be selectively implemented according to the actual requirement. In this embodiment, the first semiconductor layer 23 is an N-type semiconductor layer, and the second semiconductor layer 25 is a P-type semiconductor layer, for example.

In addition, the active layer 24 in this embodiment can be, for example but not limited to, a band gap layer or a quantum well, and may have the material including a compound composed of the III-V group or II-VI group element, such as indium gallium nitride (InGaN), gallium nitride (GaN), gallium arsenide (GaAs), gallium indium nitride (GaInN), aluminum gallium nitride (AlGaN), zinc selenide (ZnSe), zinc-doped indium gallium nitride (InGaN:Zn), aluminum gallium indium phosphide (AlInGaP) or gallium phosphide (GaP).

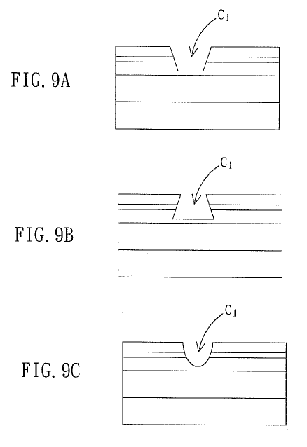

As shown in FIG. 5C, a portion of the first semiconductor layer 23, a portion of the active layer 24 and a portion of the second semiconductor layer 25 are removed to form at least one groove C₁ in the step S03. Another portion of the first semiconductor layer 23 is exposed from the groove C₁. In other words, the etching depth thereof reaches the first semiconductor layer 23. In this embodiment, the groove C₁ is formed by photo-lithography technology and etching technology such as isotropic or anisotropic etching technology. The cross-sectional shape of the groove C₁ may have a right angle, as shown in FIG. 5C, and may also be a tilt angle or a curved shape, as shown in FIGS. 9A to 9C.

As shown in FIG. 5D, at least one first electrode 26 is formed on the exposed first semiconductor layer 23 in the step S04. In this embodiment, the first electrode 26 is an N-type electrode, which can be formed on the first semiconductor layer 23 in the groove C₁ by evaporation.

As shown in FIG. 5E, an insulating layer 27 is formed in the groove C₁ in the step S05. In this embodiment, after the insulating layer 27 is formed, an auxiliary insulating layer 271 can be formed to cover a portion of the second semiconductor layer 25 around the insulating layer 27, as shown in FIG. 5F, in order to prevent hole carriers from being transmitted along a free surface when the hole carriers are inputted. Consequently, the light emitting efficiency can be further enhanced.

As shown in FIG. 5G, a conductive layer 28 is formed to cover a portion of the second semiconductor layer 25, a portion of the insulating layer 27 and/or a portion of the auxiliary insulating layer 271 in the step S06. The conductive layer 28 can be a second electrode or a transparent conductive layer. The conductive layer 28 is electrically connected to the second semiconductor layer 25 separated by the groove C₁ and a LED chip 2 is formed. In this embodiment, the conductive layer 28 is a P-type electrode, which can be formed on a portion of the second semiconductor layer 25 and a portion of the insulating layer 27 and/or a portion of the auxiliary insulating layer 271 by evaporation.

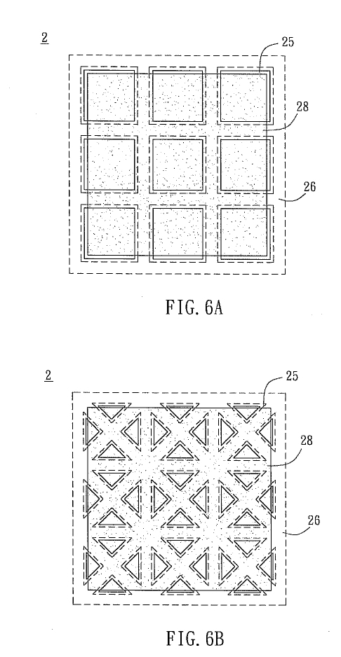

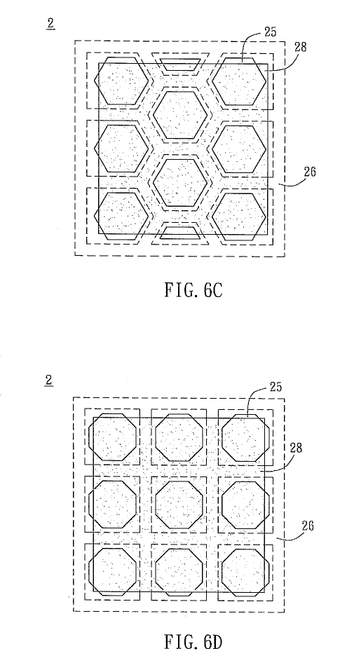

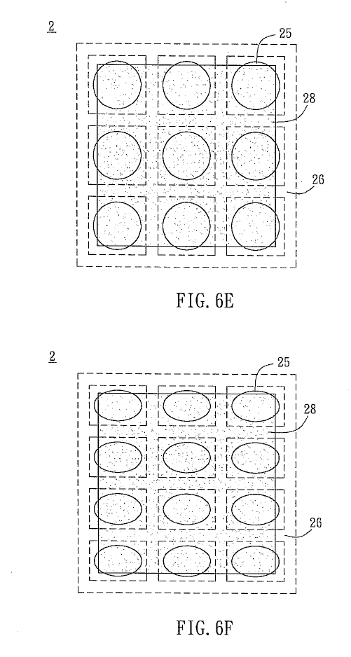

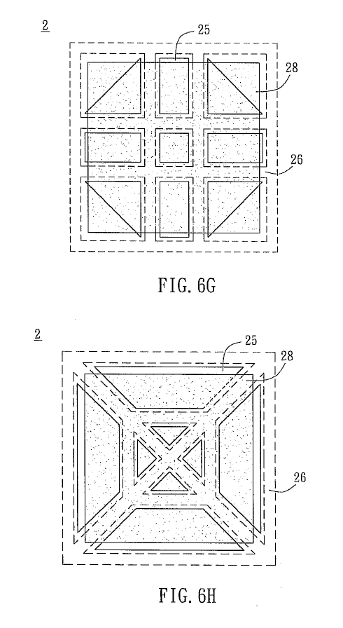

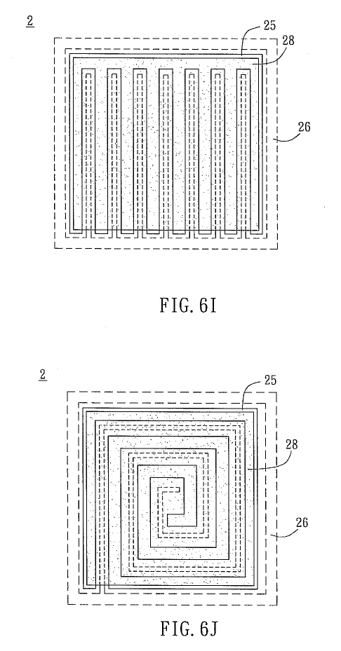

FIGS. 6A to 6J are top views showing the LED chip 2 according to this embodiment of the invention. The electrode structure of the LED chip 2 is a three-dimensional interlayer, so the first electrode (N-type electrode) 26 and the second electrode (P-type electrode) 28 are partially overlapped in a projection direction. To be noted, it is not intended to restrict the invention because the first electrode 26 and the conductive layer 28 can also be not overlapped with each other. In addition, the second semiconductor layer 25 and the active layer 24 are formed with one or more two-dimensional closed shape, such as many triangular shapes (see FIG. 6B), many tetragonal shapes (see FIG. 6A), many hexagonal shapes (see FIG. 6C), many octagonal shapes (see FIG. 6D), many circular shapes (see FIG. 6E), many elliptic shapes (see FIG. 6F), or a combination thereof (see FIGS. 6G and 6H). Alternately, the second semiconductor layer 25 and the active layer 24 are formed with a comb shape (see FIG. 61), a spiral shape (see FIG. 6J), a x-shape or a latticed shape.

As mentioned hereinabove, the LED chip 2 formed according to the above-mentioned manufacturing method has a plurality of LED units connected in parallel. The LED units with the smaller sizes are combined to form the LED chip with the larger size so that the high light emitting efficiency of the small chip and the high power load of the large chip can be provided.

### Second Embodiment

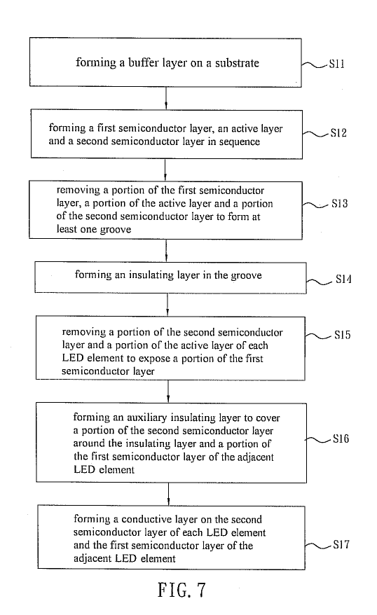

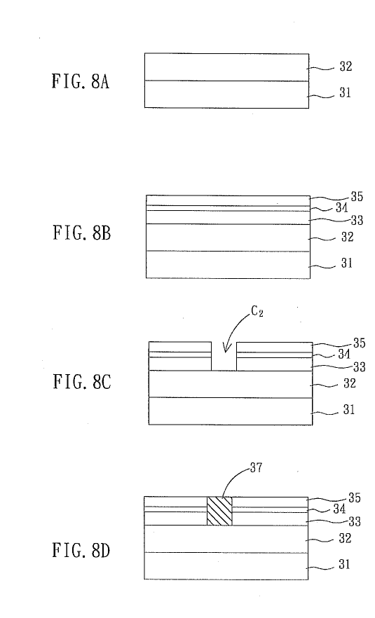

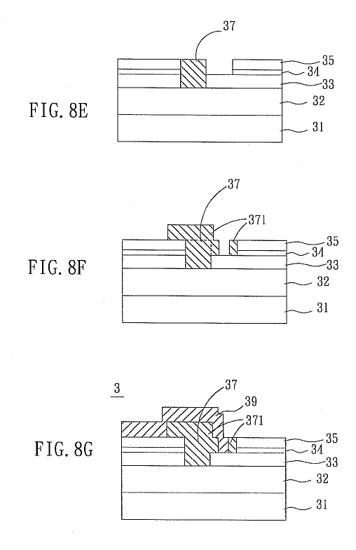

Referring to FIG. 7, a manufacturing method of a LED chip according to a second embodiment of the invention includes steps S11 to S17. Illustrations will be made with reference to FIGS. 8A to 8G.

As shown in FIG. 8A, a buffer layer 32 is formed on a substrate 31 in the step S11. A material of the substrate 31 if, for example but not limited to, sapphire, silicon, silicon carbide or an alloy, and may preferably have the high thermal conductivity. The buffer layer 32 is, for example but not limited to, a single layer or a multi-layer.

As shown in FIG. 8B, a first semiconductor layer 33, an active layer 34 and a second semiconductor layer 35 are formed sequentially on the buffer layer 32 in sequence in the step S12. The first semiconductor layer 33 can be formed on the buffer layer 32. Of course, the first semiconductor layer 33, the active layer 34 and the second semiconductor layer 35 can also be formed on an epitaxial substrate (not shown) in sequence, and then be transposed to the substrate 31 and the buffer layer 32. In brief, the semiconductor manufacturing aspect and the order are not particularly limited, and the substrate 31 and the buffer layer 32 can also be kept in a final facture or can be removed from the final facture. In other words, the step S11 can be selectively implemented according to the actual requirement. In this embodiment, the first semiconductor layer 33 is an N-type semiconductor layer, and the second semiconductor layer 35 is a P-type semiconductor layer, for example.

In addition, the active layer 34 in this embodiment is, for example but not limited to, a band gap layer or a quantum well, and may have the material including a compound composed of the III-V group or II-VI group element, such as indium gallium nitride (InGaN), gallium nitride (GaN), gallium arsenide (GaAs), gallium indium nitride (GaInN), aluminum gallium nitride (AlGaN), zinc selenide (ZnSe), zinc-doped indium gallium nitride (InGaN:Zn), aluminum gallium indium phosphide (AlInGaP) or gallium phosphide (GaP).

As shown in FIG. 8C, a portion of the first semiconductor layer 33, a portion of the active layer 34 and a portion of the second semiconductor layer 35 are removed to form at least one groove C₂ in the step S13. The groove separates the first semiconductor layer 33, the active layer 34 and the second semiconductor layer 35 into a plurality of LED units. The LED units are formed with a plurality of two-dimensional closed shapes, such as many triangular shapes (see FIG. 6B), many tetragonal shapes (see FIG. 6A), many hexagonal shapes (see FIG. 6C), many octagonal shapes (see FIG. 6D), many circular shapes (see FIG. 6E), many elliptic shapes (see FIG. 6F), or a combination thereof (see FIGS. 6G and 6H).

In this embodiment, the groove C₂ is formed by photolithography technology and etching technology such as isotropic or anisotropic etching technology. The cross-sectional shape of the groove C₂ can have a right angle, a tilt angle or a curved shape, as shown in FIGS. 9A to 9C.

As shown in FIG. 8D, an insulating layer 37 is formed in the groove C₂ in the step S14. As shown in FIG. 8E, a portion of the second semiconductor layer 35 and a portion of the active layer 34 of each LED unit are removed to expose a portion of the first semiconductor layer 33 in the step S15.

As shown in FIG. 8F, an auxiliary insulating layer 371 may further be formed to cover a portion of the second semiconductor layer 35 around the insulating layer 37 and a portion of the first semiconductor layer 33 of the adjacent LED unit in the step S16 in order to prevent hole carriers from being transmitted along a free surface when the hole carriers are inputted. Consequently, the light emitting efficiency can be further enhanced.

As shown in FIG. 8G, a conductive layer 39 is formed on the second semiconductor layer 35 of each LED unit and the first semiconductor layer 33 of the adjacent LED unit in the step S17 so that the conductive layer 39 is electrically connected to thereto. In addition, the P-type semiconductor layer and the N-type semiconductor layer are electrically connected to each other in series. In this embodiment, the material of the conductive layer 39 can be gold, silver, copper, nickel, cobalt, tin, zinc, aluminum, silicon, chromium or silicon carbide.

Finally, the first electrode and the second electrode can be selectively evaporated according to different designs. Herein, the first electrode is the N-type electrode, and the second electrode is the P-type electrode. Accordingly, the first electrode is evaporated on the first semiconductor layer 33, and the second electrode is evaporated on the second semiconductor layer 35 so that a LED chip 3 is formed.

As mentioned hereinabove, the LED chip 3 manufactured according to the above-mentioned method of the invention has a plurality of LED units connected in series. The LED units with the smaller sizes are combined to form the LED chip with the larger size so that the high light emitting efficiency of the small chip and the high power load of the large chip can be provided.

In summary, the small LED units each having the small light-emitting area are connected in series or in parallel to form a large LED unit in the LED chip and the manufacturing method thereof according to the invention. In addition, each LED unit pertains to the small-size level (the side length thereof is 300 μm), so the electrode shape needs not to have the complicated electrode pattern of the conventional high power LED device. Thus, the manufacturing processes thereof are simpler. Furthermore, the LED chip structure of the invention may be widely applied to various band gap ranges, especially the light emitting wavelength having the range from 300 nm to 800 nm, while keeping the good effect. In addition, the smaller single LED unit has high light emitting efficiency and better heat dissipating ability so that the opto-electronic converting efficiency can be enhanced and the lifetime can be lengthened.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode (LED) chip comprising:
a substrate;
a first semiconductor layer, an active layer and a second semiconductor layer formed on the substrate; and
a groove formed in the first semiconductor layer, the active layer and the second semiconductor layer.

2. The LED chip according to claim 1, wherein the first semiconductor layer is an N-type semiconductor layer, and the second semiconductor layer is a P-type semiconductor layer.

3. The LED chip according to claim 1, wherein a portion of the first semiconductor layer is exposed in the groove and the LED chip further comprises a first electrode formed on the exposed first semiconductor layer in the groove.

4. The LED chip according to claim 1, further comprising an insulating layer formed in the groove.

5. The LED chip according to claim 4, further comprising an auxiliary insulating layer formed on a portion of the insulating layer or around the insulating layer.

6. The LED chip according to claim 5, further comprising a conductive layer formed on the second semiconductor layer, the insulating layer, and/or a portion of the auxiliary insulating layer.

7. The LED chip according to claim 6, wherein a material of the conductive layer comprises gold, silver, copper, nickel, cobalt, tin, zinc, aluminum, silicon, chromium or silicon carbide.

8. The LED chip according to claim 6, wherein the conductive layer comprises a second electrode or a transparent conductive layer.

9. The LED chip according to claim 1, wherein the groove separates the first semiconductor layer, the active layer and the second semiconductor layer into a plurality of light-emitting diode (LED) units.

10. The LED chip according to claim 9, further comprising a conductive layer, wherein the second semiconductor layer of each of the LED units is electrically connected to the first semiconductor layer of one of the adjacent LED units by the conductive layer.

11. The LED chip according to claim 9, wherein the plurality of LED units connected in series or in parallel.

12. The LED chip according to claim 1, wherein the second semiconductor layer comprises a closed shape, tetragonal, hexagonal, octagonal, circular, elliptic shape, comb shape, x-shape, spiral shape or latticed shape.

13. The LED chip according to claim 1, wherein a material of the substrate comprises sapphire, silicon, silicon carbide, an alloy or thermally conductive material.

14. The LED chip according to claim 1, further comprising a buffer layer disposed between the substrate and the first semiconductor layer.

15. The LED chip according to claim 14, wherein the first semiconductor layer, the active layer and the second semiconductor layer formed on an epitaxial layer in sequence is transposed to the substrate and the buffer layer.

16. The LED chip according to claim 1, wherein the active layer is respectively a band gap layer or a quantum well, and the LED chip has a light emitting wavelength ranging from 300 nm to 800 nm.

17. The LED chip according to claim 1, wherein a material of the active layer comprises a compound composed of III-V group, II-VI group elements, indium gallium nitride (InGaN), gallium nitride (GaN), gallium arsenide (GaAs), gallium indium nitride (GaInN), aluminum gallium nitride (AlGaN), zinc selenide (ZnSe), zinc-doped indium gallium nitride (InGaN:Zn), aluminum gallium indium phosphide (AlInGaP) or gallium phosphide (GaP).

18. The LED chip according to claim 1, wherein the groove has a right angle, a tilt angle or a curved shape.

19. A manufacturing method of a light-emitting diode (LED) chip, comprising steps of:
forming a first semiconductor layer, an active layer and a second semiconductor layer in sequence;
removing a portion of the first semiconductor layer, a portion of the active layer and a portion of the second semiconductor layer to form at least one groove; forming at least one first electrode on the exposed first semiconductor layer;
forming an insulating layer in the groove; and
forming at least one second electrode on at least a portion of the second semiconductor layer.

20. The method according to claim 19, further comprising steps of:
forming a buffer layer on a substrate; and
forming the first semiconductor layer, the active layer and the second semiconductor layer on the buffer layer.

21. The method according to claim 21, wherein after the step of forming the insulating layer in the groove, the method further comprises a step of:
forming an auxiliary insulating layer on the insulating layer or around the insulating layer.

22. The method according to claim 21, further comprising a step of:
forming a conductive layer on the insulating layer and/or the auxiliary insulating layer.
